(19) United States
(12) Patent Application Publication
(10) Pub. No.: US 2012/0218721 A1
(43) Pub. Date: Aug. 30, 2012

(54) METHOD OF MANUFACTURING COMPONENT BUILT-IN MODULE AND COMPONENT BUILT-IN MODULE

(75) Inventor: Shigeo NISHIMURA, Nagaokakyo-shi (JP)

(73) Assignee: MURATA MANUFACTURING CO., LTD., Nagaokakyo-shi (JP)

(21) Appl. No.: 13/467,077

(22) Filed: May 9, 2012

Related U.S. Application Data
(63) Continuation of application No. PCT/JP2010/070648, filed on Nov. 19, 2010.

(30) Foreign Application Priority Data
Nov. 19, 2009 (JP) 2009-263477

(51) Int. Cl. H05K 7/00; H05K 3/30

(52) U.S. Cl. 361/746; 29/832

(57) ABSTRACT

A method of manufacturing a component built-in module includes a step of preparing a sheet metal; a step of providing a conductive thick-film pad over one main surface of the sheet metal by applying and curing a conductive paste; a step of providing a joining material over the conductive thick-film pad; a step of mounting a chip component onto the conductive thick-film pad with the joining material interposed therebetween; a step of providing a resin layer over the one main surface so as to cover the chip component; and a step of forming a surface electrode by patterning the sheet metal.

### BACKGROUND OF THE INVENTION

1. Field of the Invention

The present invention relates to a component built-in module including a chip component embedded within a resin layer, and a method of manufacturing such a component built-in module.

2. Description of the Related Art

In recent years, as electronic devices have become smaller, there is an increasing demand for smaller circuit boards on which a chip component such as a multilayer capacitor is to be mounted. In response to such a demand, a module is manufactured by embedding a chip component within a circuit board to reduce a mounting area of the circuit board, thereby making the circuit board smaller. In particular, a component built-in module having a chip component embedded within a resin layer has advantages in that the module is lightweight, and that the chip component to be built in is less restricted since the module does not require high-temperature firing as in the case of using a ceramic substrate.

Such a component built-in module is manufactured as described in Japanese Unexamined Patent Publication No. 2005-26573, for example. Japanese Unexamined Patent Publication No. 2005-26573 discloses a method of manufacturing a component built-in module including the steps of mounting a chip component on a sheet metal with a solder interposed therebetween, forming a resin layer so as to cover the chip component, and then patterning the sheet metal.

### SUMMARY OF THE INVENTION

The inventors of the present invention discovered that according to Japanese Unexamined Patent Publication No. 2005-26573, the solder for fixing the chip component is filled in an opening provided in an insulation layer, and a large amount of solder is required. In addition, while a bottom surface of the built-in chip component is in contact with the insulation layer, a very small gap may easily occur at an interface between the bottom surface and the insulation layer. This poses a problem in that it is highly probable that a so-called solder splash phenomenon occurs in which a melted and expanded solder flows into this gap.

Preferred embodiments of the present invention were developed based on the discovery of the above problems, and preferred embodiments of the present invention provide a method of manufacturing a component built-in module capable of reducing generation of splash of a joining material such as a solder, and provide such a component built-in module.

A method of manufacturing a component built-in module according to a preferred embodiment of the present invention includes a step of preparing a sheet metal; a step of providing a conductive thick-film pad on one main surface of the sheet metal by applying and curing a conductive paste; a step of providing a joining material over the conductive thick-film pad; a step of mounting a chip component onto the conductive thick-film pad with the joining material interposed therebetween; a step of providing a resin layer over the one main surface so as to cover the chip component; and a step of forming a surface electrode by patterning the sheet metal.

According to a preferred embodiment of the present invention, by providing the conductive thick-film pad, it is possible to increase a distance between the chip component and the sheet metal facing toward each other with the conductive thick-film pad interposed therebetween. Accordingly, it is possible to easily fill the resin layer between the chip component and the sheet metal, and to reduce splashing of the joining material such as a solder.

In the method of manufacturing a component built-in module according to a preferred embodiment of the present invention, in the step of providing the conductive thick-film pad, a surface of the conductive thick-film pad is preferably ground to be flattened after curing the conductive paste.

In this case, the chip component does not easily become inclined when mounting the chip component to the conductive thick-film pad. It is also possible to improve wettability of the joining material to the conductive thick-film pad by grinding the conductive thick-film pad to expose metallic grains contained therein.

In the method of manufacturing a component built-in module according to a preferred embodiment of the present invention, in the step of preparing the sheet metal, the sheet metal having the one main surface previously roughened is preferably prepared.

In this case, the joining material cannot easily spread over a roughened portion. Therefore, it is possible to further reduce generation of splash of the joining material such as a solder.

In the method of manufacturing a component built-in module according to a preferred embodiment of the present invention, in the step of forming the surface electrode, patterning of the metal thin film is preferably carried out such that a contact portion between the surface electrode and the conductive thick-film pad is preferably surrounded by a contact portion between the surface electrode and the resin layer.

In this case, it is possible to keep the joining material on the conductive thick-film pad even if the joining material melts and expands. Therefore, it is possible to prevent an outflow of the joining material, and to further reduce generation of splash of the joining material such as a solder.

In the method of manufacturing a component built-in module according to a preferred embodiment of the present invention further preferably includes, after the step of providing the resin layer, a step of forming a via conductor by providing a via hole in the resin layer and filling the via hole with an electrically conductive material, the via conductor having one end electrically connected to the joining material.

In this case, three-dimensional wiring is possible.

In the method of manufacturing a component built-in module according to a preferred embodiment of the present invention, in the step of forming the via conductor, the via hole is preferably provided such that the conductive thick-film pad constitutes a bottom surface of the via hole.

In this case, it is possible to prevent damage to the sheet metal when providing the via hole. Further, it is possible to reduce a height of the via conductor by a height of the conductive thick-film pad. Therefore, it is possible to reduce a diameter of the via conductor.

In the method of manufacturing a component built-in module according to a preferred embodiment of the present invention, in the step of forming the via conductor, the via hole is preferably provided such that the joining material constitutes a bottom surface of the via hole.

In this case, it is possible to reduce the height of the via conductor by a total height of the conductive thick-film pad and the joining material. Therefore, it is possible to further reduce the diameter of the via conductor.

A component built-in module according to another preferred embodiment of the present invention includes a plate-shaped resin layer including a pair of main surfaces; and a chip component provided within the resin layer, wherein a surface electrode is provided on at least one of the main surfaces of the resin layer, a conductive thick-film pad is provided on a surface of the surface electrode on a side of the resin layer, and the chip component is mounted on a surface of the conductive thick-film pad on an side opposite from the surface electrode by a joining material.

In the component built-in module according to a preferred embodiment of the present invention, the conductive thick-film pad is preferably configured by a conductive resin.

According to a method of manufacturing a component built-in module according to a preferred embodiment of the present invention and a component built-in module according to another preferred embodiment of the present invention, providing a conductive thick-film pad can increase a distance between a chip component and a sheet metal facing toward each other with the conductive thick-film pad. As a result, it is possible to easily fill a resin layer below the chip component, and to reduce generation of splash of a joining material such as a solder.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A to 1C show cross-sectional views illustrating a method of manufacturing a component built-in module according to a preferred embodiment of the present invention.

FIGS. 2D to 2F show cross-sectional views illustrating the method of manufacturing a component built-in module according to a preferred embodiment of the present invention.

FIGS. 3G and 3H show cross-sectional views illustrating the method of manufacturing a component built-in module according to a preferred embodiment of the present invention.

FIG. 4 shows a cross-sectional view illustrating an example of mounting of the component built-in module according to the present invention.

FIGS. 5A and 5B show enlarged cross-sectional views illustrating the component built-in module according to a preferred embodiment of the present invention.

### DETAILED DESCRIPTION OF THE PREFERRED EMBODIMENTS

Hereinafter, preferred embodiments of the present invention will be described.

### Preferred Embodiment 1

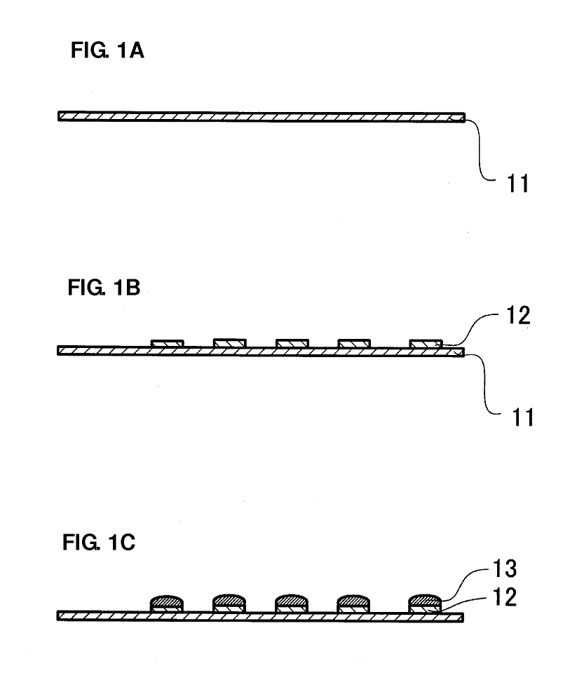

FIGS. 1A to 1C, FIGS. 2D to 2F and FIGS. 3G to 3H show cross-sectional views illustrating a method of manufacturing a component built-in module according to a preferred embodiment 1.

First, as illustrated in FIG. 1A, a sheet metal 11 is prepared. As a material of the sheet metal 11, a metal such as Cu, Ag, Au, Ag—Pt, or Ag—Pd can be used, for example. Preferably, a thickness of the sheet metal 11 is from about 9 μm to about 100 μm, for example.

It is also preferable that the sheet metal 11 whose one main surface has been previously roughened be prepared. In this case, a joining material does not easily spread at the roughened portion. Therefore, it is possible to reduce generation of splash of the joining material such as a solder. Preferably, surface roughness of the roughened portion is such that Ra=about 3 μm to about 10 μm when measured in conformity with JISB0601-2001, for example.

Next, as illustrated in FIG. 1B, a conductive thick-film pad 12 is provided on one main surface of the sheet metal 11 by applying and curing a conductive paste. The conductive paste can be applied by printing, for example. Then, the paste can be cured by heat treatment, for example. As a material of the conductive thick-film pad 12, a conductive resin such as an Ag-epoxy based conductive paste can be used, for example. Preferably, a thickness of the conductive thick-film pad 12 is from about 5 μm to about 50 μm, for example.

The conductive thick-film pad 12 preferably is formed using a thick film method such as printing. This is because, in order to provide the same pad using a plating method, it is necessary to locally grow the plating, and therefore the process becomes complicated and longer time is required when the thickness of the pad is to be increased, as well as because the plating process has a problem of a large environmental burden.

Further, while not illustrated in the drawings, it is preferable to flatten a surface of the conductive thick-film pad by grinding after the conductive paste is cured. In this case, the chip component does not easily become inclined when mounting the chip component to the conductive thick-film pad. It is also possible to improve wettability of the joining material to the conductive thick-film pad by grinding the conductive thick-film pad to expose metallic grains contained therein. An improvement of the wettability of the joining material in turn improves reliability in conductivity between the chip component and the conductive thick-film pad.

Thereafter, as illustrated in FIG. 1C, a joining material 13 is provided on the conductive thick-film pad 12. Examples of the joining material 13 include a solder. Examples of a method of providing the joining material 13 include a method of printing a solder paste by screen printing, or a method of applying a cream solder using a dispenser.

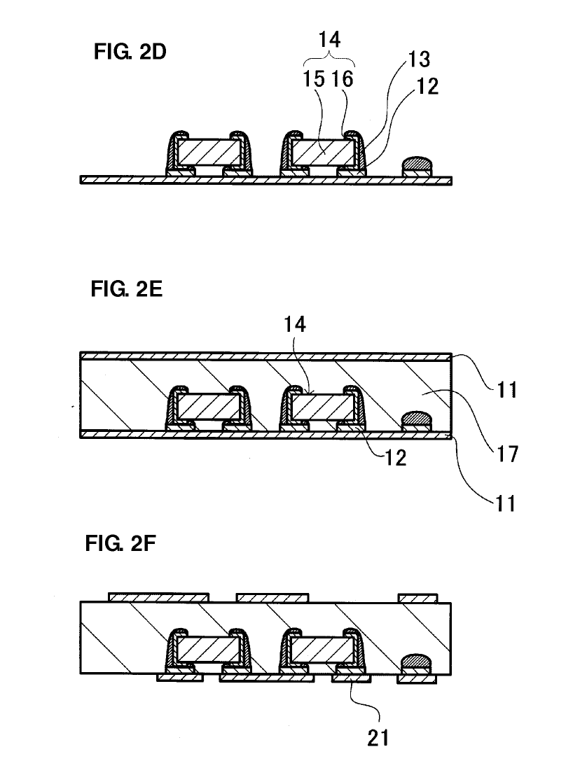

Then, as illustrated in FIG. 2D, a chip component 14 is mounted on the conductive thick-film pad 12 with the joining material 13 interposed therebetween. Specifically, the chip component 14 is placed on the joining material 13, and then the joining material 13 is melted by heating. The chip component 14 is provided with a laminated body 15 and a terminal electrode 16. Due to melting by heating, the joining material 13 wets an entire surface of the terminal electrode 16 of the chip component 14.

Thereafter, as illustrated in FIG. 2E, a resin layer 17 is provided over one main surface of the sheet metal 11 on which the chip component 14 is mounted so as to cover the chip component 14. By ensuring a height of the conductive thick-film pad 12, it is possible to increase a distance between the sheet metal 11 and the chip component 14 facing toward each other with the conductive thick-film pad 12 interposed therebetween. Accordingly, it is possible to fill the resin layer 17 below the chip component 14, and to reduce generation of splash of the joining material such as a solder.

The resin layer 17 can be provided in the following manner. A sheet-shaped uncured prepreg containing an inorganic filler and a thermo-setting resin, for example, is positioned above the sheet metal 11 and its position is adjusted. Then, by lapping the prepreg over the sheet metal 11 and the chip component 14 and by pressure-bonding the prepreg to the sheet metal 11 and the chip component 14, it is possible to provide the resin layer 17 having the chip component 14 embedded within a resin. Preferably, the prepreg is heated when pressure-bonding the prepreg. This causes the thermo-setting resin contained in the prepreg to be cured, and makes a joining condition between the resin layer 17 and the sheet metal 11 or the chip component 14 favorable. In this preferred embodiment, the sheet metal 11 is also joined to a main surface of the prepreg on a side opposite from a surface covering the chip component 14. Examples of the thermo-setting resin contained in the prepreg include an epoxy resin, a phenolic resin, and a cyanate resin. Further, examples of the inorganic filler contained in the prepreg include inorganic powder such as silica powder or alumina powder.

Subsequently, as illustrated in FIG. 2F, a surface electrode 21 is formed by patterning the sheet metal. Examples of the method of patterning the sheet metal include photolithography and etching.

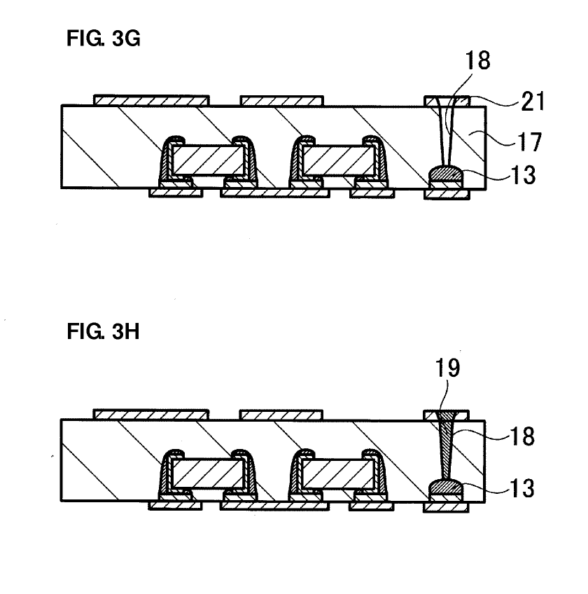

Then, as illustrated in FIG. 3G, a via hole 18 is provided through the surface electrode 21 and the resin layer 17. According to this preferred embodiment, the via hole 18 is provided such that the joining material 13 constitutes its bottom surface. Examples of the method of providing the via hole include lasering and drilling. Thereafter, as illustrated in FIG. 3H, an electrically conductive material is filled in the via hole 18, thereby forming a via conductor 19 having one end electrically connected to the joining material 13. The via conductor 19 allows three-dimensional wiring.

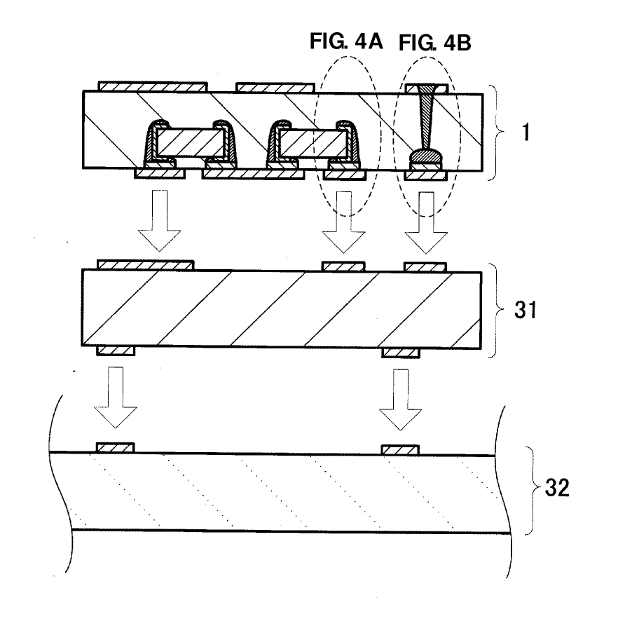

FIG. 4 shows a cross-sectional view illustrating one example of mounting of a component built-in module 1. The component built-in module 1 is mounted on a core substrate 31 by being fixed using a solder or other suitable material. The core substrate 31 is a single layer or multilayer substrate. Further, the core substrate 31 is mounted on a motherboard 32 by being fixed using a solder or other suitable material. The component built-in module 1 can be directly mounted on the motherboard 32 without the core substrate 31 interposed therebetween.

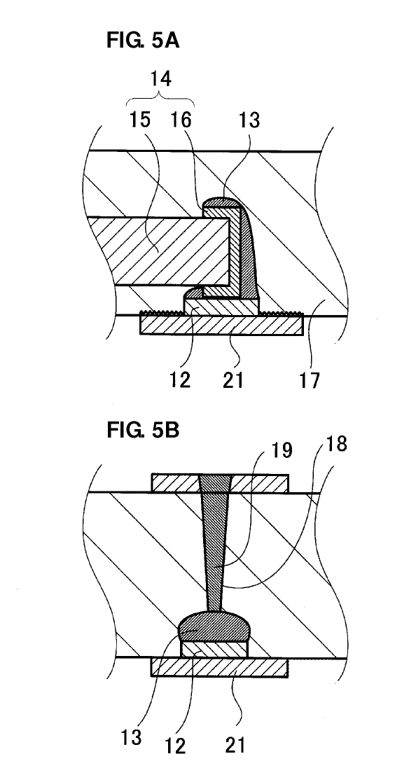

FIGS. 5A and 5B shows enlarged cross-sectional views illustrating the component built-in module of portions respectively corresponding to those represented by portions (A) and (B) in FIG. 4.

FIG. 5A shows an example in which the chip component 14 is mounted on the conductive thick-film pad 12. It is preferable to perform patterning of a metal thin film such that, as illustrated in FIG. 5A, a portion at which the surface electrode 21 and the conductive thick-film pad 12 are in contact is surrounded by a portion at which the surface electrode 21 and the resin layer 17 are in contact. In this case, the surface electrode 21 is patterned so as to cover an entire surface of the conductive thick-film pad 12 with which the surface electrode 21 is in contact. Additionally, an area of the portion at which the surface electrode 21 is in contact with the conductive thick-film pad 12 and the resin layer 17 is larger than an area of the portion at which the conductive thick-film pad 12 is in contact with the surface electrode 21. According to such a configuration, it is possible to keep the joining material 13 within a region of the surface electrode 21 even if the joining material 13 melts and expands.

Further, referring to FIG. 5A, a portion of a main surface of the surface electrode 21 at which the conductive thick-film pad 12 is provided is flattened. In addition, a portion of the main surface other than the portion at which the conductive thick-film pad 12 is provided is roughened. Because of the presence of the roughened portion, the joining material 13 cannot easily spread over the surface electrode 21 even if the joining material 13 melts and expands and overflows onto the surface electrode 21. Therefore, it is possible to prevent an outflow of the joining material 13, and to reduce generation of splash of the joining material such as a solder.

FIG. 5B shows an example in which the via conductor 19 is formed by providing the via hole 18 such that the joining material 13 provided on the conductive thick-film pad 12 constitutes its bottom surface, and filling the electrically conductive material into the via hole 18. In this case, the conductive thick-film pad 12 and the joining material 13 are present between the via conductor 19 and the surface electrode 21. Therefore, when the via hole is provided by lasering, for example, it is possible to reduce damage to the surface electrode 21. Further, it is possible to reduce the height of the via conductor 19 by an amount of the conductive thick-film pad 12 and the joining material 13. Accordingly, when the via hole is provided by lasering, for example, it is possible to reduce a diameter of the via conductor 19.

It should be noted that the via conductor 19 can be provided such that the conductive thick-film pad 12 constitutes its bottom surface. In this case as well, it is possible to obtain the same effect as in the case shown by FIG. 5B.

The method of manufacturing the component built-in module according to preferred embodiments of the present invention is not limited to the above description, and modifications can be made to the process as appropriate without departing from the gist of the invention.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method of manufacturing a component built-in module, the method comprising:
a step of preparing a sheet metal;
a step of providing a conductive thick-film pad on one main surface of the sheet metal by applying and curing a conductive paste;
a step of providing a joining material over the conductive thick-film pad;
a step of mounting a chip component onto the conductive thick-film pad with the joining material interposed therebetween;
a step of providing a resin layer over the one main surface of the sheet so as to cover the chip component; and
a step of forming a surface electrode by patterning the sheet metal.

2. The method of manufacturing a component built-in module according to claim 1, wherein in the step of providing the conductive thick-film pad, a surface of the conductive thick-film pad is ground to be flattened after curing the conductive paste.

3. The method of manufacturing a component built-in module according to claim 1, wherein in the step of preparing the sheet metal, the sheet metal including the one main surface previously roughened is prepared.

4. The method of manufacturing a component built-in module according to claim 1, wherein in the step of forming the surface electrode, patterning of the metal thin film is carried out such that a contact portion between the surface electrode and the conductive thick-film pad is surrounded by a contact portion between the surface electrode and the resin layer.

5. The method of manufacturing a component built-in module according to claim 1, further comprising after the step of providing the resin layer, a step of forming a via conductor by forming a via hole in the resin layer and filling the via hole with an electrically conductive material, the via conductor including one end electrically connected to the joining material.

6. The method of manufacturing a component built-in module according to claim 5, wherein in the step of forming the via conductor, the via hole is provided such that the conductive thick-film pad constitutes a bottom surface of the via hole.

7. The method of manufacturing a component built-in module according to claim 5, wherein in the step of forming the via conductor, the via hole is provided such that the joining material constitutes a bottom surface of the via hole.

8. A component built-in module comprising:
a plate-shaped resin layer including a pair of main surfaces; and
a chip component provided within the resin layer; wherein
a surface electrode is provided on at least one of the main surfaces of the resin layer, a conductive thick-film pad is provided on a surface of the surface electrode on a side of the resin layer, and the chip component is mounted on a surface of the conductive thick-film pad on an side opposite from the surface electrode by a joining material.

9. The component built-in module according to claim 8, wherein the conductive thick-film pad includes a conductive resin.
